(19) United States
(12) Patent Application Publication
(10) Pub. No.: US 2015/0083476 A1
(43) Pub. Date: Mar. 26, 2015

(54) DEVICE EMBEDDED PRINTED CIRCUIT BOARD AND METHOD OF MANUFACTURING THE SAME

(71) Applicant: Samsung Electro-Mechanics Co., Ltd., Suwon-si (KR)

(72) Inventors: Jong Rip Kim, Suwon-si (KR); Han Kim, Suwon-si (KR)

(73) Assignee: Samsung Electro-Mechanics Co., Ltd., Suwon-si (KR)

(21) Appl. No.: 14/228,099

(22) Filed: Mar. 27, 2014

(30) Foreign Application Priority Data
Sep. 25, 2013 (KR) 10-2013-0113995

(51) Int. Cl. H05K 1/11; H05K 3/46; H05K 3/42; H05K 1/18; H05K 3/30

(52) U.S. Cl. CPC H05K 1/113; H05K 1/183; H05K 3/30; H05K 3/429; H05K 3/4644; H05K 2201/09481
USPC 174/260; 174/266; 29/852; 29/832

(57) ABSTRACT

Disclosed herein is a device embedded printed circuit board, including: a first core layer having a first via and having a via land for a first connection pad disposed on a lower surface thereof; a build-up layer formed on the first core layer and having a plurality of circuit layers including a second connection pad, a plurality of insulating layer disposed between the plurality of circuit layers, and a second via connecting the plurality of circuit layers; and a second core layer formed on the build-up layer and having a cavity.

### CROSS REFERENCE TO RELATED APPLICATION

This application claims the benefit of Korean Patent Application No. 10-2013-0113995, filed on Sep. 25, 2013, entitled “Device Embedded Printed Circuit Board And Method Of Manufacturing The Same”, which is hereby incorporated by reference in its entirety into this application.

### BACKGROUND OF THE INVENTION

1. Technical Field

The present invention relates to a device embedded printed circuit board and a method of manufacturing the same.

2. Description of the Related Art

A warpage problem always occurs due to unbalance of a coefficient of thermal expansion between stacked materials in a multilayered printed circuit board which has a stacked form of a heterogeneous material. However, the warpage of the printed circuit board causes problems, such as a solder ball bridge or delamination at the time of a package assembly, which is a cause of reducing a product yield. Recently, with a demand for thinness of mobile electronic products, packaging industries tend to make a semiconductor package substrate thin so as to reduce a thickness of the package. Further, in order to overcome an environmental problem due to the use of solder including lead, the use of lead-free solder having a high melting point has increased. Therefore, as the semiconductor package substrate is gradually thin, deformations, such as warpage and torsion, due to thermal stress, moisture absorption, etc., which occur during the manufacturing of the substrate are larger and as a reflow temperature condition rises even at the time of packaging, the warpage phenomenon which occurs in the substrate increases, which causes a serious yield problem and has emerged as a main cause of defect occurrence.

### PRIOR ART DOCUMENT

### Patent Document

(Patent Document 1) Korean Patent Laid-Open Publication No. 2012-0077510

### SUMMARY OF THE INVENTION

The present invention has been made in an effort to provide a device embedded printed circuit board in which a copper clad laminate (CCL) having the same coefficient of thermal expansion (CTE) is disposed on both surfaces of a build-up layer so as to reduce warpage, and a method of manufacturing the same.

According to a preferred embodiment of the present invention, there is provided a device embedded printed circuit board, including: a first core layer having a first via and having a via land for a first connection pad disposed on a lower surface thereof; a build-up layer formed on the first core layer and having a plurality of circuit layers including a second connection pad, a plurality of insulating layer disposed between the plurality of circuit layers, and a second via connecting the plurality of circuit layers; and a second core layer formed on the build-up layer and having a cavity.

The device embedded printed circuit board may further include: a first device disposed in the cavity, wherein the first core layer may have a device embedded cavity.

The device embedded printed circuit board may further include: a second device connected to the exposed second connection pad and embedded in the cavity of the second core layer.

The device embedded printed circuit board may further include: a second device connected to and mounted on an upper end of the exposed second via through the cavity of the second core layer, wherein the first via may have a tapered shape in which a diameter of the via is wide downwardly.

The first and second core layers may be an insulating resin in which a reinforcement material is impregnated.

The first and second core layers may have a coefficient of thermal expansion (CTE) of 1 to 5 ppm/° C.

A coefficient of thermal expansion (CTE) of the first and second core layers may be smaller than that of the build-up layer.

The device embedded printed circuit board may further include: a first solder resist layer having an opening through which the first connection pad is exposed and disposed on a lower portion of the first core layer.

The device embedded printed circuit board may further include: a second solder resist layer having an opening through which the second connection pad is exposed and disposed on the exposed build-up layer.

The first and second vias may have a tapered shape in which a diameter thereof is wide downwardly.

The first via may have a hourglass shape and the second via may have a tapered shape in which a diameter thereof is narrow downwardly.

The device embedded printed circuit board may further include: an external connection terminal disposed on the first connection pad.

The device embedded printed circuit board may further include: an outer circuit layer disposed on the second core layer.

The device embedded printed circuit board may further include: a solder resist layer disposed on the outer circuit layer.

According to another preferred embodiment of the present invention, there is provided a method of manufacturing a device embedded printed circuit board, including: preparing a first core layer which has a first via and has a via land for a first connection pad disposed on a lower surface thereof; preparing a carrier; forming the first core layer on both surfaces of the carrier; forming a build-up layer having a plurality of circuit layers including a second connection pad, a plurality of insulating layer disposed between the plurality of circuit layers, and a second via connecting the plurality of circuit layers on the first core layer; and forming a second core layer having a cavity on the build-up layer; and separating the first core layer from the carrier.

The preparing of the first core layer may further include: forming a device embedded cavity on the first core layer; and embedding a first device in the device embedded cavity.

The method of manufacturing a device embedded printed circuit board may further include: prior to the embedding of the first device, attaching a protective film to a lower surface of the first core layer; and removing the protective film after the separating of the first core layer from the carrier.

The method of manufacturing a device embedded printed circuit board may further include: after the removing of the protective film, forming a first solder resist layer having an opening through which the first connection pad is exposed.

The method of manufacturing a device embedded printed circuit board may further include: after the separating of the carrier from the first core layer, forming a second solder resist layer having an opening through which the second connection pad is exposed on the build-up layer exposed through the cavity of the second core layer.

The core layer may be an insulating resin in which a reinforcement material is impregnated.

The first and second core layers may have a coefficient of thermal expansion (CTE) of 1 to 5 ppm/° C.

A coefficient of thermal expansion (CTE) of the first and second core layers may be smaller than that of the build-up layer.

The first via may have a hourglass shape and the second via may have a tapered shape in which a diameter thereof is narrow downwardly.

The method of manufacturing a device embedded printed circuit board may further include: after the separating of the first core layer, forming an external connection terminal on the first connection pad.

The method of manufacturing a device embedded printed circuit board may further include: prior to the separating of the first core layer from the carrier, forming an outer circuit layer on the second core layer.

The method of manufacturing a device embedded printed circuit board may further include: after the forming of the outer circuit layer on the second core layer, forming a solder resist layer on the outer circuit layer.

According to still another preferred embodiment of the present invention, there is provided a method of manufacturing a device embedded printed circuit board, including: preparing a second core layer having a cavity; preparing a carrier; forming the second core layer on both surfaces of the carrier; mounting a second device in a cavity of the second core layer so as to contact one surface of the carrier; forming a build-up layer having a plurality of circuit layers, a plurality of insulating layer disposed between the plurality of circuit layers, and a second via connecting the plurality of circuit layers on the second core layer on which the second device is mounted; forming a first core layer having a first via and having a via land for a first connection pad on the build-up layer; and separating the second core layer from the carrier.

The method of manufacturing a device embedded printed circuit board may further include: prior to the separating of the second core layer from the carrier, forming a first solder resist layer having an opening through which the first connection pad is exposed.

The method of manufacturing a device embedded printed circuit board may further include: after the separating of the first core layer, forming an external connection terminal on the first connection pad.

The preparing of the first core layer may include: forming a device embedded cavity on the first core layer; and embedding a first device in the device embedded cavity.

The first and second core layers may be an insulating resin in which a reinforcement material is impregnated.

The first and second core layers may have a coefficient of thermal expansion (CTE) of 1 to 5 ppm/° C.

A coefficient of thermal expansion (CTE) of the first and second core layers may be smaller than that of the insulating layer.

The first and second vias may have a tapered shape in which a diameter thereof is wide downwardly.

The second device may be connected to and mounted on an upper end of the exposed second via through the cavity of the second core layer, wherein the second via may have a tapered shape in which a diameter of the via is wide downwardly.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view illustrating a structure of a device embedded printed circuit board according to a first preferred embodiment of the present invention;

FIG. 2 is a cross-sectional view illustrating a structure of a device embedded printed circuit board according to a second preferred embodiment of the present invention;

FIG. 3 is a cross-sectional view illustrating a structure of a device embedded printed circuit board according to a third preferred embodiment of the present invention;

FIG. 4 is a cross-sectional view illustrating a structure of a device embedded printed circuit board according to a fourth preferred embodiment of the present invention;

FIG. 5 is a cross-sectional view illustrating a structure of a device embedded printed circuit board according to a fifth preferred embodiment of the present invention;

FIG. 6 is a cross-sectional view illustrating a structure of a device embedded printed circuit board according to a sixth preferred embodiment of the present invention;

FIGS. 7 to 17 are process flow charts illustrating a method of manufacturing a device embedded printed circuit board according to another preferred embodiment of the present invention; and

FIGS. 18 to 25 are process flow charts illustrating a method of manufacturing a device embedded printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

Device Embedded Printed Circuit Board

### First Preferred Embodiment

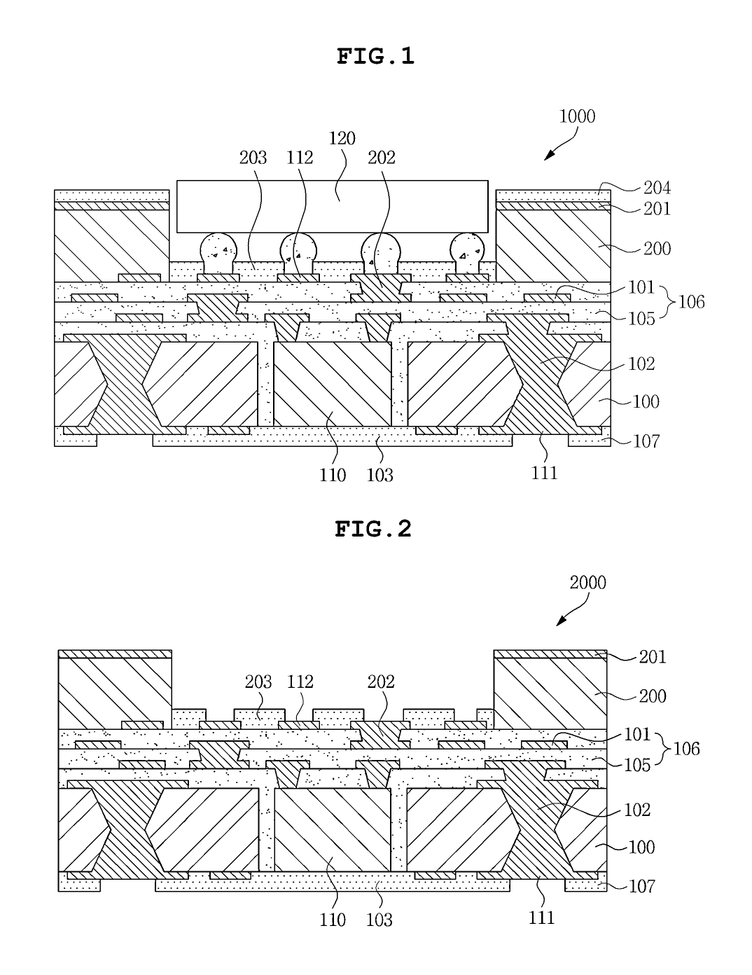

FIG. 1 is a cross-sectional view illustrating a structure of a device embedded printed circuit board 1000 according to a first preferred embodiment of the present invention. As illustrated in FIG. 1, the device embedded printed circuit board 1000 according to the first preferred embodiment of the present invention includes a first core layer 100 which has a first via 102 and has a via land for a first connection pad 111 disposed on a lower surface thereof, a build-up layer 106 which is disposed on the first core layer 100 and includes a plurality of circuit layers 101 including a second connection pad 112, a plurality of insulating layers 105 disposed between the plurality of circuit layers 101, and a second via 202 connecting the plurality of circuit layers 101, and a second core layer 200 which is disposed on the build-up layer 106 and has a cavity 205.

As the insulating layer 105, a resin insulating layer may be used. As a material of the resin insulating layer, a thermosetting resin such as epoxy resin, a thermoplastic resin such as polyimide resin, a resin having a reinforcement material such as glass fiber or inorganic filler impregnated in the thermosetting resin and the thermoplastic resin, for example, a prepreg may be used. In addition, the thermosetting resin and/or a photo-curable resin, and the like, may be used; however, the material of the resin insulating layer is not particularly limited thereto.

If the conductive metals for the circuit may be used for the circuit layer 101 in the circuit board field, any conductive metal may be used without being limited and in the printed circuit board, copper may typically be used.

The exposed circuit layer may be further provided with the surface treatment layer (not illustrated), if necessary.

Any surface treatment layer known in the art may be used without being particularly limited, but the surface treatment layer may be formed by, for example, electro gold plating, immersion gold plating, organic solderability preservative (OSP), immersion tin plating, immersion silver plating, electroless nickel and immersion gold (ENIG), direct immersion gold (DIG) plating, hot air solder leveling (HASL), and the like.

Herein, the first core layer 100 has a device embedded cavity 103 and the first device 110 may be embedded in the cavity 103.

Further, a second device 120 is connected to the exposed second connection pad 112 and may be embedded in the cavity 205 of the second core layer 200.

Other detailed components of the devices 110 and 120 are omitted and schematically illustrated in FIG. 1, but it can be appreciated by those skilled in the art that the semiconductor devices having all the structures known to the art may be applied to the semiconductor device embedded printed circuit board according to the preferred embodiment of the present invention without being not particularly limited.

Further, the first and second core layers 100 and 200 may be an insulating resin in which the reinforcement material is impregnated.

Here, the reinforcement material may be the prepreg and the glass fiber, but is not particularly limited thereto.

Further, the coefficient of thermal expansion (CTE) of the first and second core layers 100 and 200 may be 1 to 5 ppm/° C. Further, the coefficient of thermal expansion (CTE) of the first and second core layers may be smaller than that of the build-up layer 106 which is disposed between the first and second core layers.

Here, a lower portion of the first core layer 100 may be provided with a first solder resist layer 107 having an opening through which the first connection pad 111 is exposed.

Further, a second solder resist layer 203 having an opening through which the second connection pad 112 is exposed may be disposed on the exposed build-up layer 106.

Further, although not illustrated in the first connection pad 111, an external connection terminal may be further disposed thereon.

Here, an outer circuit layer 201 may be disposed on the second core layer 200 and a solder resist layer 204 may be further disposed on the outer circuit layer 201.

Further, the first via 102 has a hourglass shape and the second via 202 may have a tapered shape in which a diameter of the via is narrow downwardly.

### Second Preferred Embodiment

FIG. 2 is a cross-sectional view illustrating a structure of a device embedded printed circuit board 2000 according to a second preferred embodiment of the present invention.

As illustrated in FIG. 2, the device embedded printed circuit board 2000 according to the second preferred embodiment of the present invention includes the first core layer 100 which has the first via 102 and has the via land for the first connection pad 111 disposed on the lower surface thereof, the build-up layer 106 which is disposed on the first core layer 100 and includes the plurality of circuit layers 101 including the second connection pad 112, the plurality of insulating layers 105 disposed between the plurality of circuit layers 101, and the second via 202 connecting the plurality of circuit layers 101, and the second core layer 200 which is disposed on the build-up layer 106 and has the cavity 205.

Herein, the first core layer 100 has the device embedded cavity 103 and the first device 110 may be embedded in the cavity 103.

Further, although not illustrated, the second device 120 is connected to the exposed second connection pad 112 and may be embedded in the cavity 205 of the second core layer 200.

Further, the first and second core layers 100 and 200 may be the insulating resin in which the reinforcement material is impregnated.

Here, the reinforcement material may be the prepreg and the glass fiber, but is not particularly limited thereto.

Further, the coefficient of thermal expansion (CTE) of the first and second core layers 100 and 200 may be 1 to 5 ppm/° C. Further, the coefficient of thermal expansion (CTE) of the first and second core layers may be smaller than that of the build-up layer 106 which is disposed between the first and second core layers.

Here, the lower portion of the first core layer 100 may be provided with the first solder resist layer 107 having the opening through which the first connection pad 111 is exposed.

Further, the second solder resist layer 203 having the opening through which the second connection pad 112 is exposed may be disposed on the exposed build-up layer 106.

Further, although not illustrated in the first connection pad 111, the external connection terminal may be further disposed thereon.

Here, the outer circuit layer 201 may be disposed on the second core layer 200.

### Third Preferred Embodiment

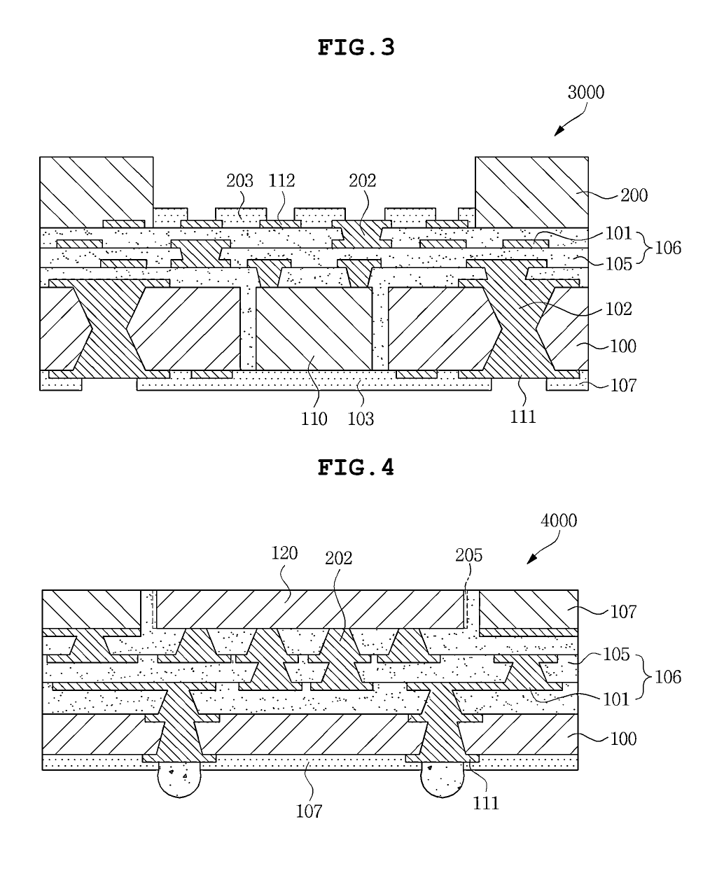

FIG. 3 is a cross-sectional view illustrating a structure of a device embedded printed circuit board 3000 according to a third preferred embodiment of the present invention.

As illustrated in FIG. 3, the device embedded printed circuit board 3000 according to the third preferred embodiment of the present invention includes the first core layer 100 which has the first via 102 and has the via land for the first connection pad 111 disposed on the lower surface thereof, the build-up layer 106 which is disposed on the first core layer 100 and includes the plurality of circuit layers 101 including the second connection pad 112, the plurality of insulating layers 105 disposed between the plurality of circuit layers 101, and the second via 202 connecting the plurality of circuit layers 101, and the second core layer 200 which is disposed on the build-up layer 106 and has the cavity 205.

Herein, the first core layer 100 has the device embedded cavity 103 and the first device 110 may be embedded in the cavity 103.

Further, although not illustrated, the second device 120 is connected to the exposed second connection pad 112 and may be embedded in the cavity 205 of the second core layer 200.

Further, the first and second core layers 100 and 200 may be the insulating resin in which the reinforcement material is impregnated.

Here, the reinforcement material may be the prepreg and the glass fiber, but is not particularly limited thereto. Further, the coefficient of thermal expansion (CTE) of the first and second core layers 100 and 200 may be 1 to 5 ppm/° C. Further, the coefficient of thermal expansion (CTE) of the first and second core layers may be smaller than that of the build-up layer 106 which is disposed between the first and second core layers.

Here, the lower portion of the first core layer 100 may be provided with the first solder resist layer 107 having the opening through which the first connection pad 111 is exposed.

Further, the second solder resist layer 203 having the opening through which the second connection pad 112 is exposed may be disposed on the exposed build-up layer 106.

Further, although not illustrated in the first connection pad 111, the external connection terminal may be further disposed thereon.

### Fourth Preferred Embodiment

FIG. 4 is a cross-sectional view illustrating a structure of a device embedded printed circuit board 4000 according to a fourth preferred embodiment of the present invention.

As illustrated in FIG. 4, the device embedded printed circuit board 4000 according to the fourth preferred embodiment of the present invention includes the first core layer 100 which has the first via 102 and has the via land for the first connection pad 111 disposed on the lower surface thereof, the build-up layer 106 which is disposed on the first core layer 100 and includes the plurality of circuit layers 101, the plurality of insulating layers 105 disposed between the plurality of circuit layers 101, and the second via 202 connecting the plurality of circuit layers 101, and the second core layer 200 which is disposed on the build-up layer 106 and has the cavity 205.

Further, the first and second core layers 100 and 200 may be the insulating resin in which the reinforcement material is impregnated.

Here, the reinforcement material may be the prepreg and the glass fiber, but is not particularly limited thereto.

Further, the coefficient of thermal expansion (CTE) of the first and second core layers 100 and 200 may be 1 to 5 ppm/° C. Further, the coefficient of thermal expansion (CTE) of the first and second core layers may be smaller than that of the build-up layer 106 which is disposed between the first and second core layers.

Here, the lower portion of the first core layer 100 may be provided with the first solder resist layer 107 having the opening through which the first connection pad 111 is exposed.

Further, the external connection terminal may be further disposed on the first connection pad 111.

Further, the first and second vias 102 and 202 may have the tapered shape in which the diameter thereof is wide downwardly.

Further, the second device 120 may be connected to and mounted on an upper end of the second via 202 which is exposed through the cavity 205 of the second core layer 200.

### Fifth Preferred Embodiment

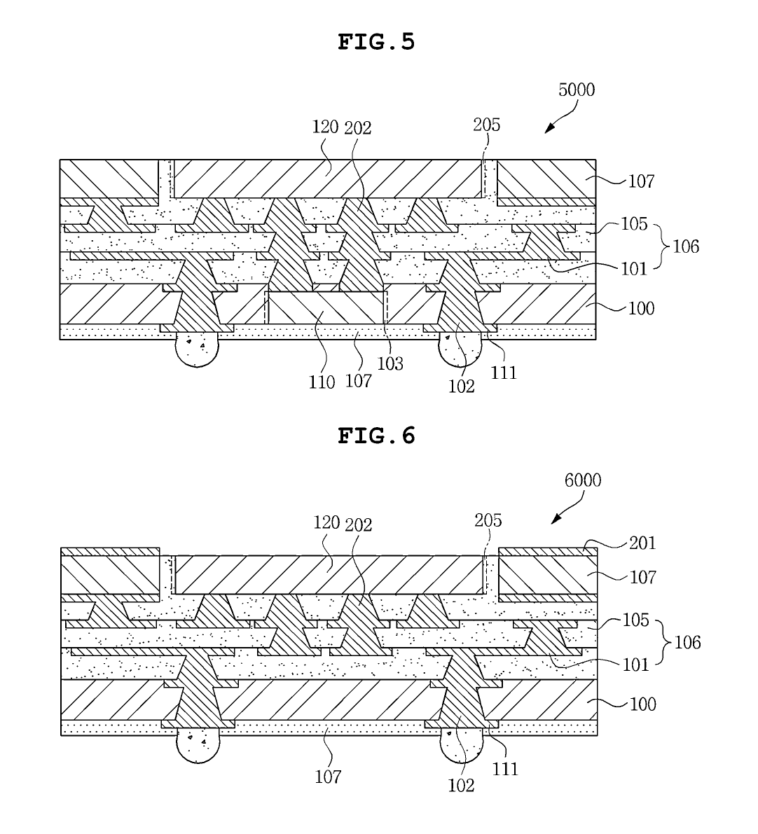

FIG. 5 is a cross-sectional view illustrating a structure of a device embedded printed circuit board 5000 according to a fifth preferred embodiment of the present invention.

As illustrated in FIG. 5, the device embedded printed circuit board 5000 according to the fifth preferred embodiment of the present invention includes the first core layer 100 which has the first via 102 and has the via land for the first connection pad 111 disposed on the lower surface thereof, the build-up layer 106 which is disposed on the first core layer 100 and includes the plurality of circuit layers 101, the plurality of insulating layers 105 disposed between the plurality of circuit layers 101, and the second via 202 connecting the plurality of circuit layers 101, and the second core layer 200 which is disposed on the build-up layer 106 and has the cavity 205.

Herein, the first core layer 100 has the device embedded cavity 103 and the first device 110 may be embedded in the cavity 103.

Further, the first and second core layers 100 and 200 may be the insulating resin in which the reinforcement material is impregnated.

Here, the reinforcement material may be the prepreg and the glass fiber, but is not particularly limited thereto.

Further, the coefficient of thermal expansion (CTE) of the first and second core layers 100 and 200 may be 1 to 5 ppm/° C. Further, the coefficient of thermal expansion (CTE) of the first and second core layers may be smaller than that of the build-up layer 106 which is disposed between the first and second core layers.

Here, the lower portion of the first core layer 100 may be provided with the first solder resist layer 107 having the opening through which the first connection pad 111 is exposed.

Further, the external connection terminal may be further disposed on the first connection pad 111.

Further, the first and second vias 102 and 202 may have the tapered shape in which the diameter thereof is wide downwardly.

Further, the second device 120 may be connected to and mounted on an upper end of the second via 202 which is exposed through the cavity 205 of the second core layer 200.

### Sixth Preferred Embodiment

FIG. 6 is a cross-sectional view illustrating a structure of a device embedded printed circuit board 6000 according to a sixth preferred embodiment of the present invention.

As illustrated in FIG. 6, the device embedded printed circuit board 6000 according to the sixth preferred embodiment of the present invention includes the first core layer 100 which has the first via 102 and has the via land for the first connection pad 111 disposed on the lower surface thereof, the build-up layer 106 which is disposed on the first core layer 100 and includes the plurality of circuit layers 101, the plurality of insulating layers 105 disposed between the plurality of circuit layers 101, and the second via 202 connecting the plurality of circuit layers 101, and the second core layer 200 which is disposed on the build-up layer 106 and has the cavity 205.

Further, the first and second core layers 100 and 200 may be the insulating resin in which the reinforcement material is impregnated.

Here, the reinforcement material may be the prepreg and the glass fiber, but is not particularly limited thereto.

Further, the coefficient of thermal expansion (CTE) of the first and second core layers 100 and 200 may be 1 to 5 ppm/° C. Further, the coefficient of thermal expansion (CTE) of the first and second core layers may be smaller than that of the build-up layer 106 which is disposed between the first and second core layers.

Here, the lower portion of the first core layer 100 may be provided with the first solder resist layer 107 having the opening through which the first connection pad 111 is exposed.

Further, the external connection terminal may be further disposed on the first connection pad 111.

Further, the first and second vias 102 and 202 may have the tapered shape in which the diameter thereof is wide downwardly.

Further, the second device 120 may be connected to and mounted on an upper end of the second via 202 which is exposed through the cavity 205 of the second core layer 200.

Here, the outer circuit layer 201 may be disposed on the second core layer 200.

### Method of Manufacturing Device Embedded Printed Circuit Board

Method of Manufacturing First Device Embedded Printed Circuit Board

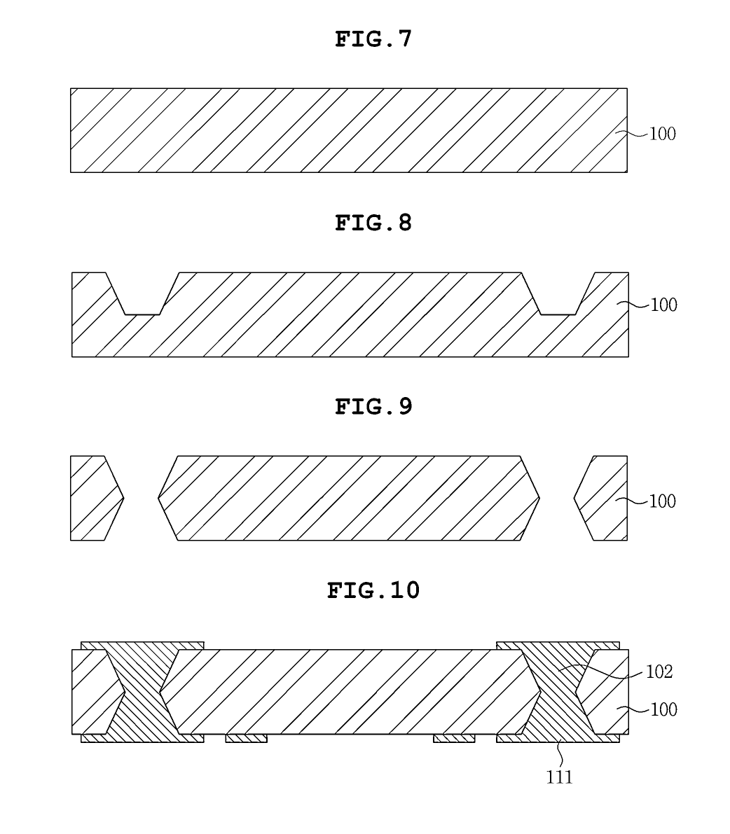

FIGS. 7 to 17 are process flow charts illustrating a method of manufacturing a device embedded printed circuit board according to another preferred embodiment of the present to invention.

As illustrated in FIG. 7, the first core layer 100 is prepared.

In this case, the first core layer 100 may be made of the insulating resin in which the reinforcement material is impregnated.

As illustrated in FIG. 8, an upper via hole on the first core layer 100 may be machined.

Here, as a method of machining the via hole, CO2 laser and YAG laser may be used, but the preferred embodiment of the present invention is not particularly limited thereto.

As illustrated in FIG. 9, a lower via hole may be machined at a position corresponding to the upper via hole on the first core layer 100.

As illustrated in FIG. 10, the upper via hole and the lower via hole are plated to be able to form the first via 102 including the first connection pad 111.

The first via 102 may have the hourglass shape.

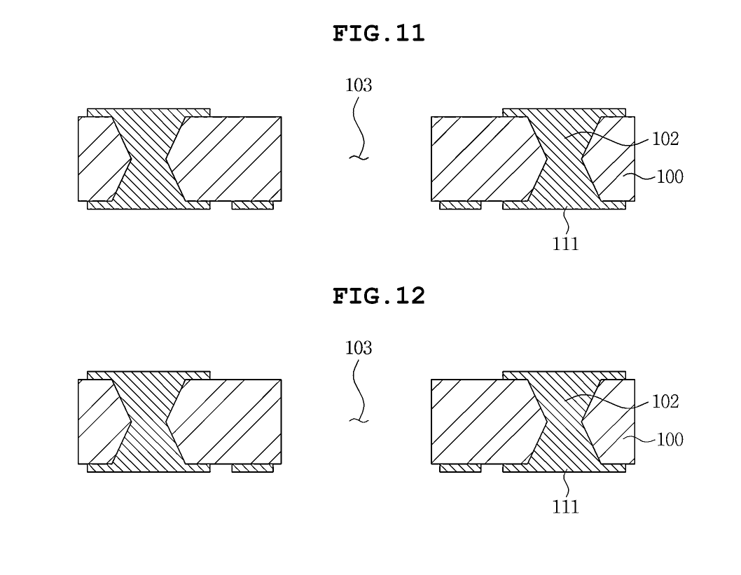

As illustrated in FIG. 11, the device embedded cavity 103 may be disposed on the first core layer 100.

As illustrated in FIG. 12, a protective film 104 may be attached to the lower surface of the first core layer 100.

Further, the first device 110 may be embedded through the cavity 103 on the protective film 104.

Other detailed components of the device 110 are omitted and schematically illustrated in the above drawings, but it can be appreciated by those skilled in the art that the semiconductor devices having all the structures known to the art may be applied to the semiconductor device embedded printed circuit board according to the preferred embodiment of the present invention without being not particularly limited.

As illustrated in FIG. 13, the first core layer 100 may be disposed on both surfaces of a carrier 300.

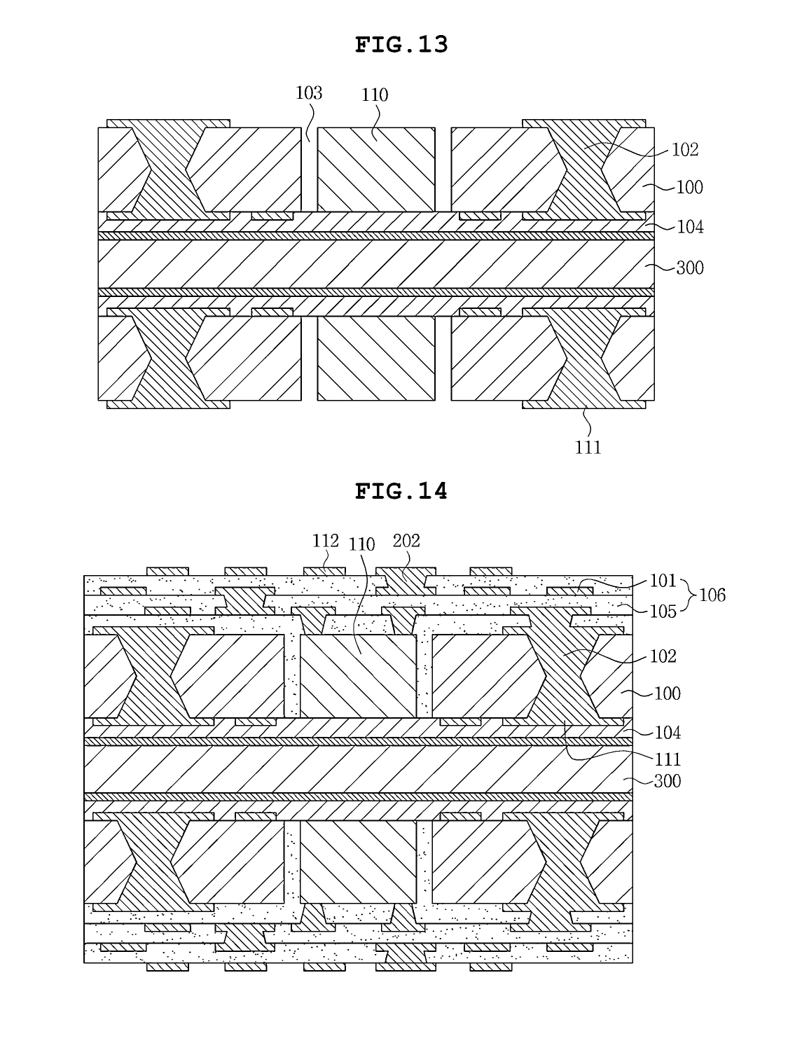

As illustrated in FIG. 14, the build-up layer 106 which includes the plurality of circuit layers 101 including the second connection pad 112, the plurality of insulating layers 105 disposed between the plurality of circuit layers 101, and the second via 202 connecting the plurality of circuit layers 101 may be disposed on the first core layer 100.

If the conductive metals for the circuit may be used for the circuit layer 101 in the circuit board field, any conductive metal may be used without being limited and in the printed circuit board, copper may typically be used.

The exposed circuit layer may be further provided with the surface treatment layer (not illustrated), if necessary.

Any surface treatment layer known in the art may be used without being particularly limited, but the surface treatment layer be formed by, for example, electro gold plating, immersion gold plating, organic solderability preservative (OSP), immersion tin plating, immersion silver plating, electroless nickel and immersion gold (ENIG), direct immersion gold (DIG) plating, hot air solder leveling (HASL), and the like.

As the insulating layer 105, the resin insulating layer may be used As the material of the resin insulating layer, the thermosetting resin such as epoxy resin, the thermoplastic resin such as polyimide resin, the resin having the reinforcement material such as glass fiber or inorganic filler impregnated in the thermosetting resin and the thermoplastic resin, for example, the prepreg may be used. In addition, the thermosetting resin and/or the photo-curable resin, and the like, may be used; however, the material of the resin insulating layer is not particularly limited thereto.

Here, the second via 202 may have the tapered shape in which the diameter of the via is narrow downwardly.

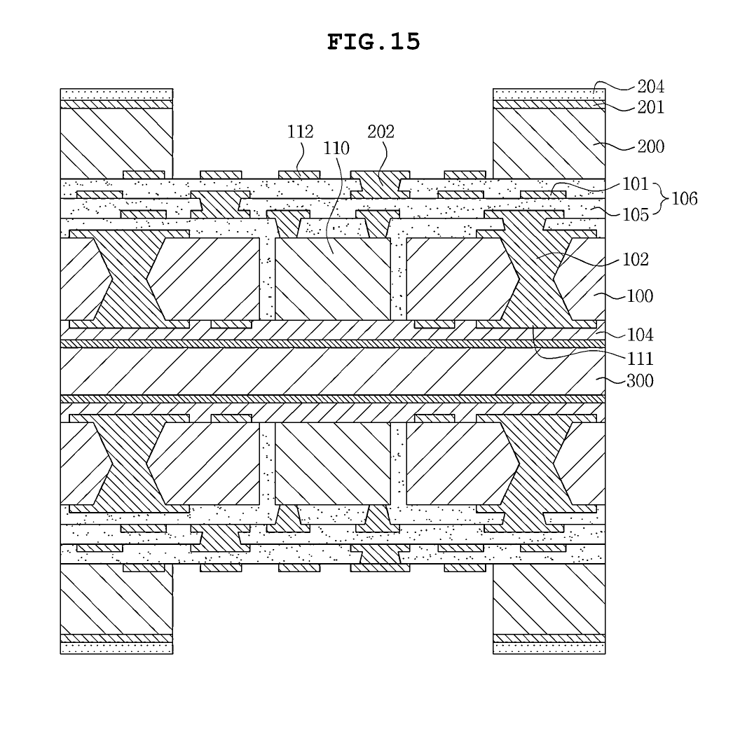

As illustrated in FIG. 15, the second core layer 200 having the cavity may be disposed on the build-up layer 106.

In this case, the second core layer 200 may be made of the insulating resin in which the reinforcement material is impregnated.

Further, the outer circuit layer 201 may be disposed on the second core layer 200.

Here, a solder resist layer 204 may be further disposed on the outer circuit layer 201.

Further, the coefficient of thermal expansion (CTE) of the first and second core layers 100 and 200 may be 1 to 5 ppm/° C., in which the coefficient of thermal expansion (CTE) of the first and second core layers may be smaller than that of the build-up layer 106 which is disposed between the first and second core layers 100 and 200.

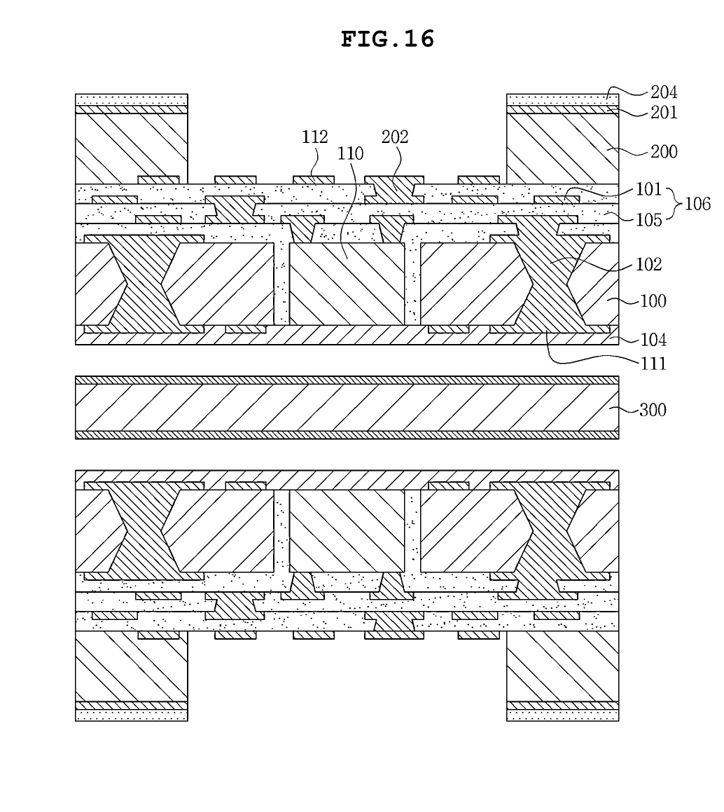

As illustrated in FIG. 16, the carrier 300 may be separated from the first core layer 100.

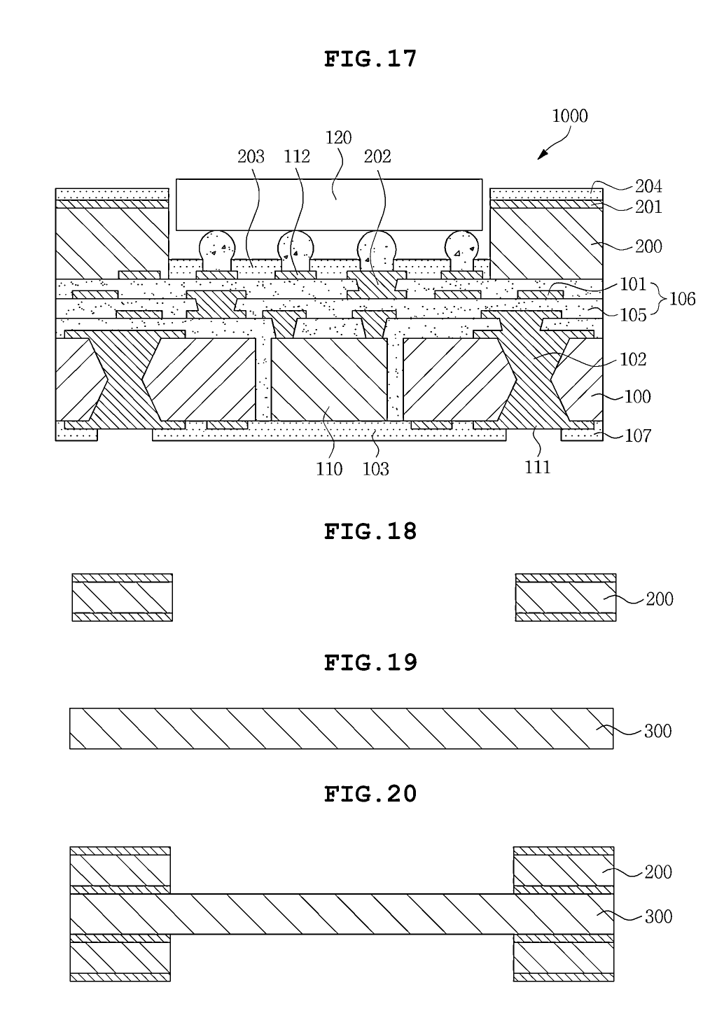

As illustrated in FIG. 17, the lower surface of the separated first core layer 100 may be provided with the first solder resist layer 107 having the opening through which the first connection pad 111 is exposed.

Although not illustrated on the lower surface of the first solder resist layer 107, the external connection terminal may be further disposed thereon.

Further, the second solder resist layer 203 having the opening through which the second connection pad 112 is exposed may be disposed on the build-up layer 106 which is exposed through the cavity 205 of the second core layer 200. Further, the second device 120 may be embedded through the cavity 205 of the second core layer 200 so as to be electrically connected to the second connection pad 112.

### Method of Manufacturing Second Device Embedded Printed Circuit Board

FIGS. 18 to 25 are process flow charts illustrating a method of manufacturing a device embedded printed circuit board according to another preferred embodiment of the present invention.

As illustrated in FIG. 18, the second core layer 200 having the cavity is prepared.

In this case, the second core layer 200 may be made of the insulating resin in which the reinforcement material is impregnated.

As illustrated in FIG. 19, the carder 300 is prepared.

As illustrated in FIG. 20, the second core layer 200 is disposed on both surfaces of the prepared carder 300.

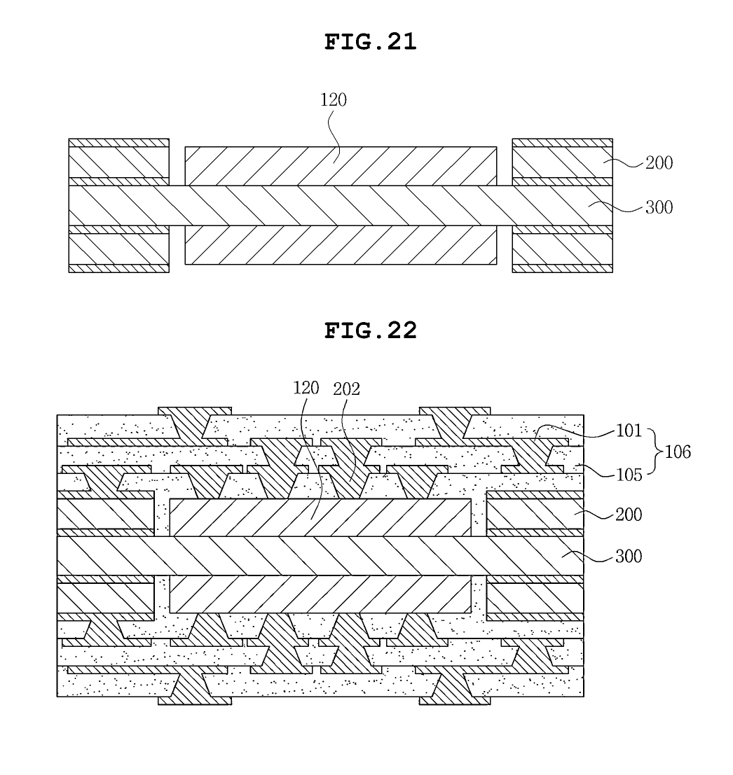

As illustrated in FIG. 21, the second device 120 may be embedded in the cavity of the second core layer 200 so as to contact one surface of the carrier.

As illustrated in FIG. 22, the build-up layer 106 which includes the plurality of circuit layers 101, the plurality of insulating layers 105 disposed between the plurality of circuit layers 101, and the second via 202 connecting the plurality of circuit layers 101 may be disposed on the second core layer 200 in which the second device 120 is embedded.

If the conductive metals for the circuit may be used for the circuit layer 101 in the circuit board field, any conductive metal may be used without being limited and in the printed circuit board, copper may typically be used.

The exposed circuit layer may be further provided with the surface treatment layer (not illustrated), if necessary.

Any surface treatment layer known in the art may be used without being particularly limited, but the surface treatment layer be formed by, for example, the electro gold plating, the immersion gold plating, the organic solderability preservative (OSP), the immersion tin plating, the immersion silver plating, the electroless nickel and immersion gold (ENIG), the direct immersion gold (DIG) plating, the hot air solder leveling (HASL), and the like.

As the insulating layer 105, the resin insulating layer may be used As the material of the resin insulating layer, the thermosetting resin such as epoxy resin, the thermoplastic resin such as polyimide resin, the resin having a reinforcement material such as glass fiber or inorganic filler impregnated in the thermosetting resin and the thermoplastic resin, for example, the prepreg may be used. In addition, the thermosetting resin and/or the photo-curable resin, and the like, may be used; however, the material of the resin insulating layer is not particularly limited thereto.

Here, the second via 202 may have the tapered shape in which the diameter of the via is wide downwardly.

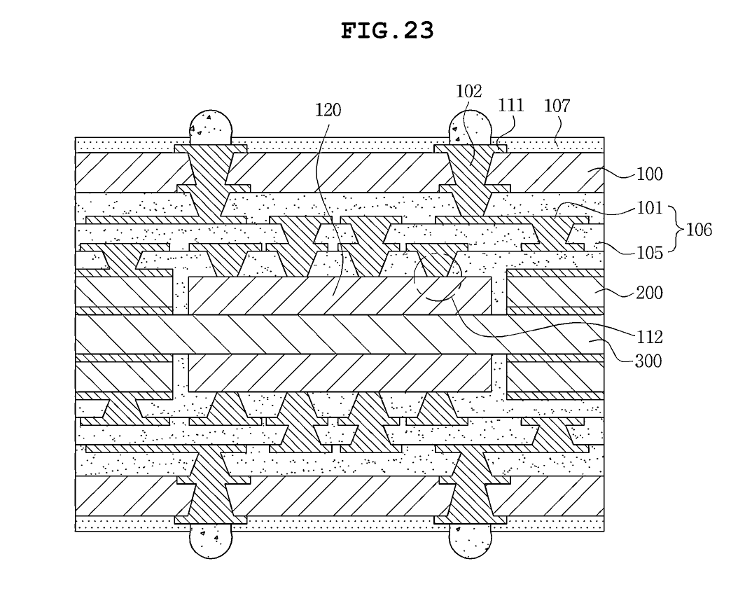

As illustrated in FIG. 23, the first core layer 100 which has the first via 102 and has the via land for the first connection pad 111 may be disposed on the build-up layer 106.

Further, although not illustrated in the first core layer 100, the device embedded cavity may be disposed thereon and the first device 110 may be embedded in the cavity.

Further, the coefficient of thermal expansion (CTE) of the first and second core layers 100 and 200 may be 1 to 5 ppm/° C., in which the coefficient of thermal expansion (CTE) of the first and second core layers may be smaller than that of the build-up layer 106 which is disposed between the first and second core layers 100 and 200.

Here, the first via 102 may have the tapered shape in which the diameter of the via is wide downwardly.

Further, the first solder resist layer 107 having the opening through which the first connection pad 111 is exposed may be disposed and the external connection terminal may be further disposed on the first connection pad 111.

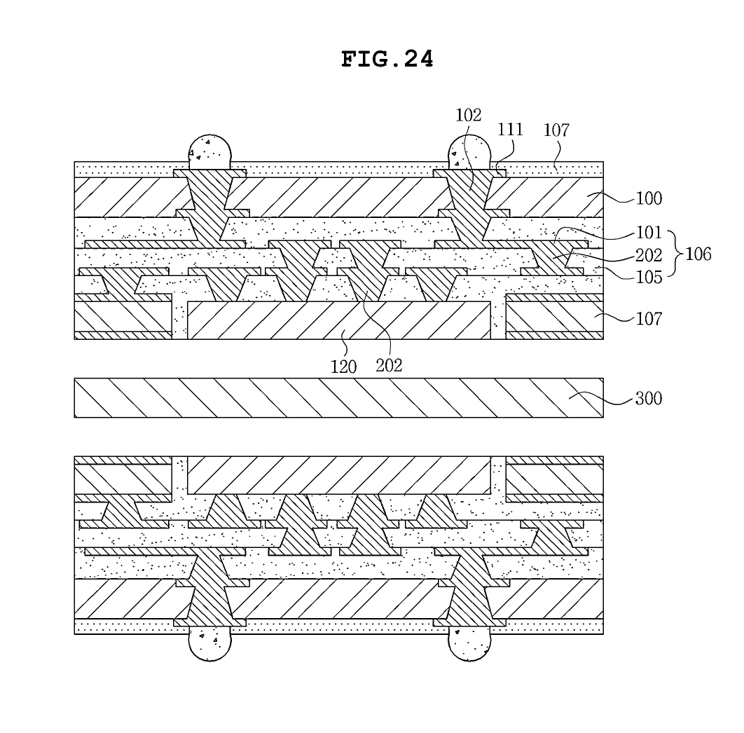

As illustrated in FIG. 24, the second core layer 200 may be separated from the carrier 300.

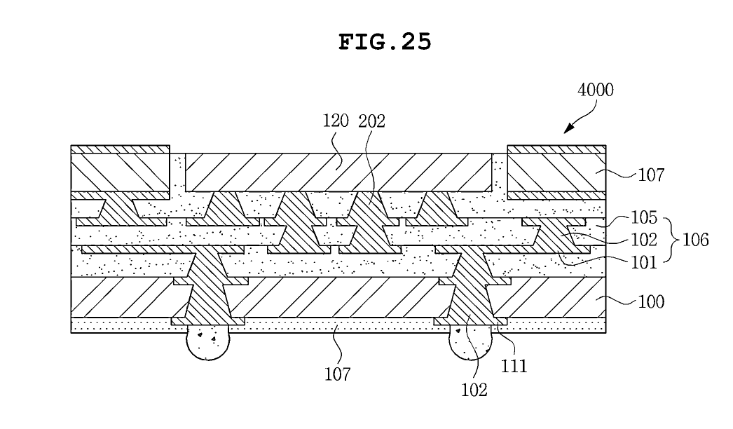

As illustrated in FIG. 25, the outer circuit layer may be further disposed on the second core layer 200.

According to the device embedded printed circuit board according to the preferred embodiments of the present invention, the copper clad laminate (CCL) having the same coefficient of thermal expansion (CTE) is disposed on both surfaces of the build-up layer, thereby reducing the warpage. As a result, it is possible to secure the yield at the time of mounting the package.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A device embedded printed circuit board, comprising:
a first core layer having a first via and having a via land for a first connection pad disposed on a lower surface thereof;
a build-up layer formed on the first core layer and having a plurality of circuit layers including a second connection pad, a plurality of insulating layer disposed between the plurality of circuit layers, and a second via connecting the plurality of circuit layers; and
a second core layer formed on the build-up layer and having a cavity.

2. The device embedded printed circuit board as set forth in claim 1, further comprising:
a first device disposed in the cavity, wherein the first core layer has a device embedded cavity.

3. The device embedded printed circuit board as set forth in claim 1, further comprising:
a second device connected to the exposed second connection pad and embedded in the cavity of the second core layer.

4. The device embedded printed circuit board as set forth in claim 1, further comprising:
a second device connected to and mounted on an upper end of the exposed second via through the cavity of the second core layer, wherein the first via has a tapered shape in which a diameter of the via is wide downwardly.

5. The device embedded printed circuit board as set forth in claim 1, wherein the first and second core layers are an insulating resin in which a reinforcement material is impregnated.

6. The device embedded printed circuit board as set forth in claim 1, wherein the first and second core layers have a coefficient of thermal expansion (CIE) of 1 to 5 ppm/° C.

7. The device embedded printed circuit board as set forth in claim 1, wherein a coefficient of thermal expansion (CIE) of the first and second core layers is smaller than that of the build-up layer.

8. The device embedded printed circuit board as set forth in claim 1, further comprising:
a first solder resist layer having an opening through which the first connection pad is exposed and disposed on a lower portion of the first core layer.

9. The device embedded printed circuit board as set forth in claim 1, further comprising:
a second solder resist layer having an opening through which the second connection pad is exposed and disposed on the exposed build-up layer.

10. The device embedded printed circuit board as set forth in claim 1, wherein the first and second vias have a tapered shape in which a diameter thereof is wide downwardly.

11. The device embedded printed circuit board as set forth in claim 1, wherein the first via has a hourglass shape and the second via has a tapered shape in which a diameter thereof is narrow downwardly.

12. The device embedded printed circuit board as set forth in claim 1, further comprising:
an external connection terminal disposed on the first connection pad.

13. The device embedded printed circuit board as set forth in claim 1, further comprising:
an outer circuit layer disposed on the second core layer.

14. The device embedded printed circuit board as set forth in claim 13, further comprising:
a solder resist layer disposed on the outer circuit layer.

15. A method of manufacturing a device embedded printed circuit board, comprising:
preparing a first core layer which has a first via and has a via land for a first connection pad disposed on a lower surface thereof;
preparing a carrier;
forming the first core layer on both surfaces of the carrier;
forming a build-up layer having a plurality of circuit layers including a second connection pad, a plurality of insulating layer disposed between the plurality of circuit layers, and a second via connecting the plurality of circuit layers on the first core layer;
forming a second core layer having a cavity on the build-up layer; and
separating the first core layer from the carrier.

16. The method as set forth in claim 15, wherein the preparing of the first core layer includes:
forming a device embedded cavity on the first core layer; and
embedding a first device in the device embedded cavity.

17. The method as set forth in claim 16, further comprising:
prior to the embedding of the first device, attaching a protective film to a lower surface of the first core layer; and
removing the protective film after the separating of the first core layer from the carrier.

18. The method as set forth in claim 17, further comprising:
after the removing of the protective film, forming a first solder resist layer having an opening through which the first connection pad is exposed.

19. The method as set forth in claim 15, further comprising:
after the separating of the carrier from the first core layer, forming a second solder resist layer having an opening through which the second connection pad is exposed on the build-up layer exposed through the cavity of the second core layer.

20. The method as set forth in claim 15, wherein the core layer is an insulating resin in which a reinforcement material is impregnated.

21. The method as set forth in claim 15, wherein the first and second core layers have a coefficient of thermal expansion (CTE) of 1 to 5 ppm/° C.

22. The method as set forth in claim 15, wherein a coefficient of thermal expansion (CTE) of the first and second core layers is smaller than that of the build-up layer.

23. The method as set forth in claim 15, wherein the first via has a hourglass shape and the second via has a tapered shape in which a diameter thereof is narrow downwardly.

24. The method as set forth in claim 15, further comprising:
after the separating of the first core layer, forming an external connection terminal on the first connection pad.

25. The method as set forth in claim 15, further comprising:
prior to the separating of the first core layer from the carrier, forming an outer circuit layer on the second core layer.

26. The method as set forth in claim 25, further comprising:
after the forming of the outer circuit layer on the second core layer, forming a solder resist layer on the outer circuit layer.

27. A method of manufacturing a device embedded printed circuit board, comprising:
preparing a second core layer having a cavity;
preparing a carrier;
forming the second core layer on both surfaces of the carrier;
mounting a second device in a cavity of the second core layer so as to contact one surface of the carrier;
forming a build-up layer having a plurality of circuit layers, a plurality of insulating layer disposed between the plurality of circuit layers, and a second via connecting the plurality of circuit layers on the second core layer on which the second device is mounted;
forming a first core layer having a first via and having a via land for a first connection pad on the build-up layer; and
separating the second core layer from the carrier.

28. The method as set forth in claim 27, further comprising:
prior to the separating of the second core layer from the carrier, forming a first solder resist layer having an opening through which the first connection pad is exposed.

29. The method as set forth in claim 28, further comprising:
after the separating of the first core layer, forming an external connection terminal on the first connection pad.

30. The method as set forth in claim 27, wherein the preparing of the first core layer includes:
forming a device embedded cavity on the first core layer; and
embedding a first device in the device embedded cavity.

31. The method as set forth in claim 27, wherein the first and second core layers are an insulating resin in which a reinforcement material is impregnated.

32. The method as set forth in claim 27, wherein the first and second core layers have a coefficient of thermal expansion (CTE) of 1 to 5 ppm/° C.

33. The method as set forth in claim 27, wherein a coefficient of thermal expansion (CTE) of the first and second core layers is smaller than that of the insulating layer.

34. The method as set forth in claim 27, wherein the first and second vias have a tapered shape in which a diameter thereof is wide downwardly.

35. The method as set forth in claim 27, wherein the second device is connected to and mounted on an upper end of the exposed second via through the cavity of the second core layer, wherein the second via has a tapered shape in which a diameter of the via is wide downwardly.
